(19) United States
(12) Patent Application Publication
(10) Pub. No.: US 2025/0040456 A1
(43) Pub. Date: Jan. 30, 2025

(54) LOW RESISTANCE SWITCHES

(71) Applicant: QUALCOMM Incorporated, San Diego, CA (US)

(72) Inventors: Thomas Hua-Min WILLIAMS, Irvine, CA (US); Khaja Ahmad SHAIK, Douglas, Cork (IE); Conor ROCHE, Cork (IE); Hanil LEE, San Diego, CA (US); Roger Lee MILLS, Pflugerville, TX (US); Keyurkumar Karsanbhai KANSAGRA, Bangalore, Karnataka (IN); Smeeta HEGGOND, Bagalkot, Karnataka (IN); Giby SAMSON, San Diego, CA (US)

(21) Appl. No.: 18/715,921

(22) PCT Filed: Feb. 1, 2023
(86) PCT No.: PCT/US23/61728

§ 371 Date: Jun. 3, 2024

(30) Foreign Application Priority Data
Feb. 17, 2022 (IN) 202241008380

(51) Int. Cl. H10N 70/20; H10N 79/00

(52) U.S. Cl. CPC H10N 70/253; H10N 79/00

(57) ABSTRACT

In certain aspects, a die includes fins extending in a first direction, gates formed over the fins, wherein the gates extend in a second direction that is perpendicular to the first direction, and source/drain contact layers formed over the fins, wherein the source/drain contact layers extend in the second direction, and the gates and the source/drain contact layers are interleaved. The die also includes a first gate metal layer, a second gate metal layer, wherein the source/drain contact layers are between the first gate metal layer and the second gate metal layer in the second direction, first gate vias electrically coupling the first gate metal layer to the gates, and second gate vias electrically coupling the second gate metal layer to the gates.

### CROSS-REFERENCE TO RELATED APPLICATION

This application claims priority to and the benefit of Indian patent application Ser. No. 202241008380 filed in the Indian Patent Office on Feb. 17, 2022, the entire content of which is incorporated herein as if fully set forth below in its entirety and for all applicable purposes.

### BACKGROUND

### Field

Aspects of the present disclosure relate generally to transistors, and more particularly, to layouts for transistors.

### BACKGROUND

A semiconductor die may include a large number of transistors used as switches (e.g., to control power to one or more circuits). It is desirable that transistors used as switches have low on-resistance to reduce the current-resistance (IR) voltage drop across the transistors. Adding more transistors in parallel reduces the on-resistance, but at the expense of more area. As technology nodes become smaller, parasitic resistances in the transistors increase, making it more challenging to achieve low on-resistance.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a die. The die includes fins extending in a first direction, gates formed over the fins, wherein the gates extend in a second direction that is perpendicular to the first direction, and source/drain contact layers formed over the fins, wherein the source/drain contact layers extend in the second direction, and the gates and the source/drain contact layers are interleaved. The die also includes a first gate metal layer, a second gate metal layer, wherein the source/drain contact layers are between the first gate metal layer and the second gate metal layer in the second direction, first gate vias electrically coupling the first gate metal layer to the gates, and second gate vias electrically coupling the second gate metal layer to the gates.

A second aspect relates to a die. The die includes first fins extending in a first direction, second fins extending in the first direction, and gates formed over the first fins and the second fins, wherein the gates extend in a second direction that is perpendicular to the first direction, and each of the gates extends contiguously over the first fins and the second fins. The die also includes first source/drain contact layers formed over the first fins, wherein the first source/drain contact layers extend in the second direction, and the gates and the first source/drain contact layers are interleaved. The die also includes second source/drain contact layers formed over the second fins, wherein the second source/drain contact layers extend in the second direction, and the gates and the second source/drain contact layers are interleaved. The die also includes a first gate metal layer, a second gate metal layer, wherein the first source/drain contact layers are between the first gate metal layer and the second gate metal layer in the second direction, and a third gate metal layer, wherein the second source/drain contact layers are between the second gate metal layer and the third gate metal layer in the second direction. The die further includes first gate vias electrically coupling the first gate metal layer to the gates, second gate vias electrically coupling the second gate metal layer to the gates, and third gate vias electrically coupling the third gate metal layer to the gates.

A third aspect relates to a system. The system includes a switch. The switch includes fins extending in a first direction, gates formed over the fins, wherein the gates extend in a second direction that is perpendicular to the first direction, and source/drain contact layers formed over the fins, wherein the source/drain contact layers extend in the second direction, and the gates and the source/drain contact layers are interleaved. The switch also includes source/drain metal layers, wherein each of the source/drain metal layers extends over at least a portion of a respective one of the source/drain contact layers, source/drain vias electrically coupling the source/drain contact layers to the source/drain metal layers, a first gate metal layer, and a second gate metal layer, wherein the source/drain contact layers are between the first gate metal layer and the second gate metal layer in the second direction. The switch also includes first gate vias electrically coupling the first gate metal layer to the gates, and second gate vias electrically coupling the second gate metal layer to the gates. The system also includes a power switch controller coupled to the first gate metal layer and the second gate metal layer, a power distribution network coupled to a first subset of the source/drain metal layers, and a circuit coupled to a second subset of the source/drain metal layers.

### BRIEF DESCRIPTION OF THE DRAWINGS

FIG. 1A shows an exemplary layout of gates and fins according to certain aspects of the present disclosure.

FIG. 1B shows an example of cuts in the gates according to certain aspects of the present disclosure.

FIG. 1C shows an example of source/drain contact layers formed on the fins according to certain aspects of the present disclosure.

FIG. 1D shows an example of cuts in the source/drain contact layers according to certain aspects of the present disclosure.

FIG. 1E shows an example of vias distributed on the source/drain contact layers and the gates according to certain aspects of the present disclosure.

FIG. 1F shows an example of source/drain metal layers and gate metal layers according to certain aspects of the present disclosure.

FIG. 2A shows an exemplary layout of gates, fins, and source/drain contact layers according to certain aspects of the present disclosure.

FIG. 2B shows an example of cuts in the source/drain contact layers according to certain aspects of the present disclosure.

FIG. 2C shows an example of vias distributed on the source/drain contact layers and the gates according to certain aspects of the present disclosure.

FIG. 2D shows an example of source/drain metal layers and gate metal layers according to certain aspects of the present disclosure.

FIG. 2E shows a side view of the structure in FIG. 2D according to certain aspects of the present disclosure.

FIG. 3 shows an example of contiguous gates extending across multiple transistors according to certain aspects of the present disclosure.

FIG. 4 shows an example of power switches implemented with transistors according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

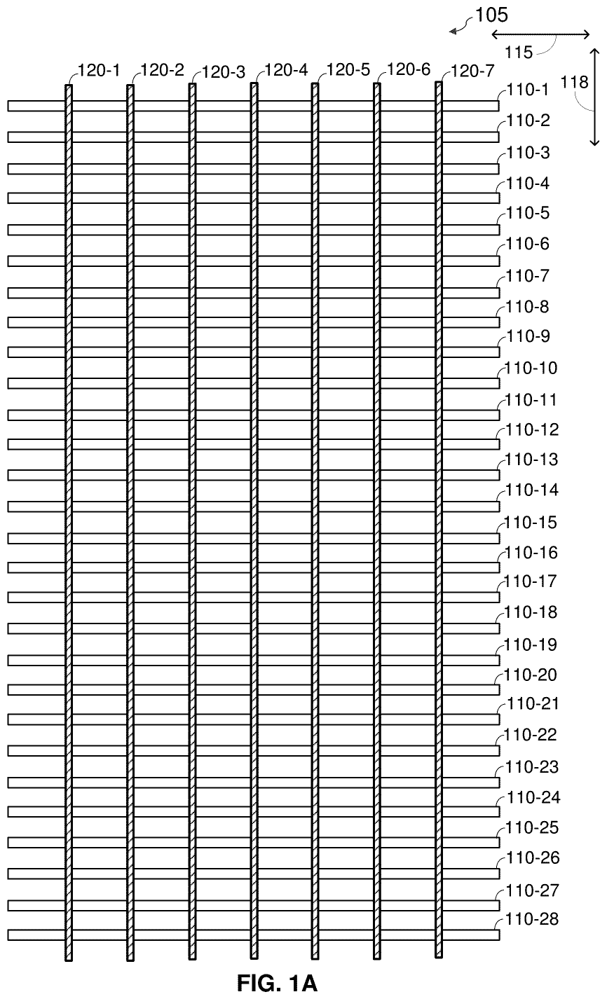

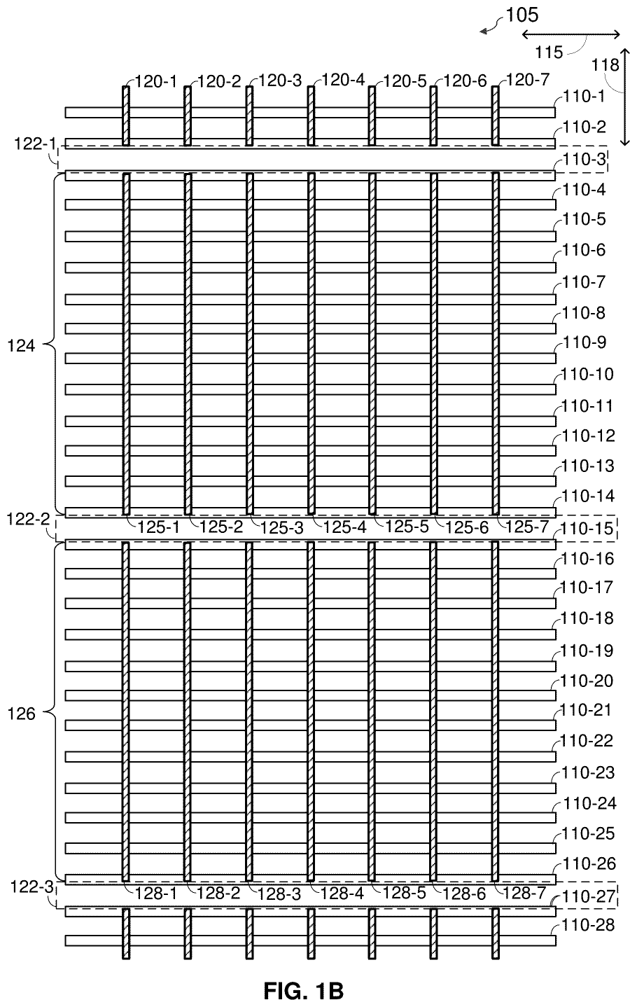

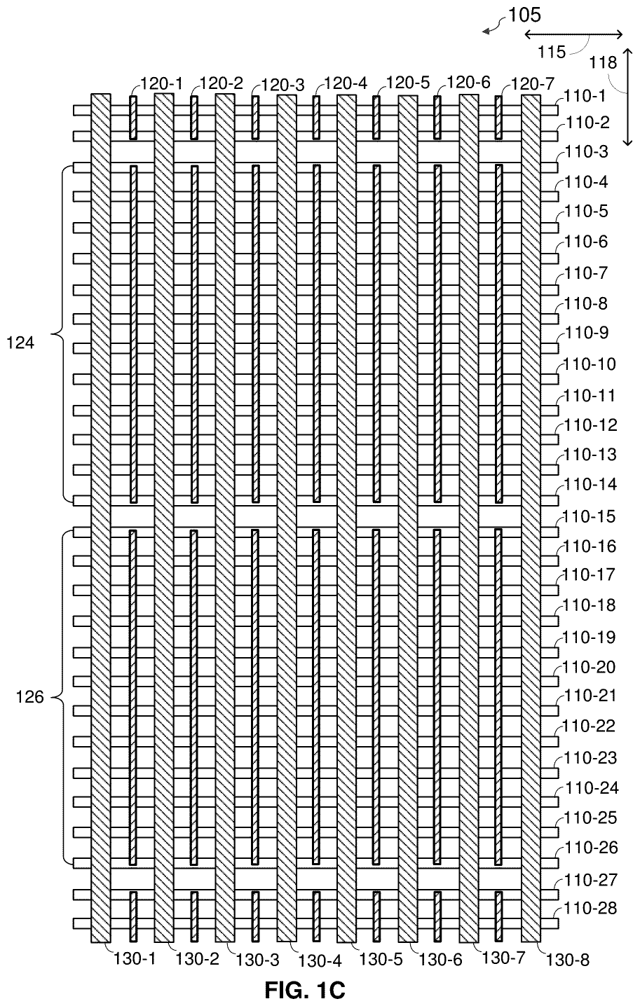

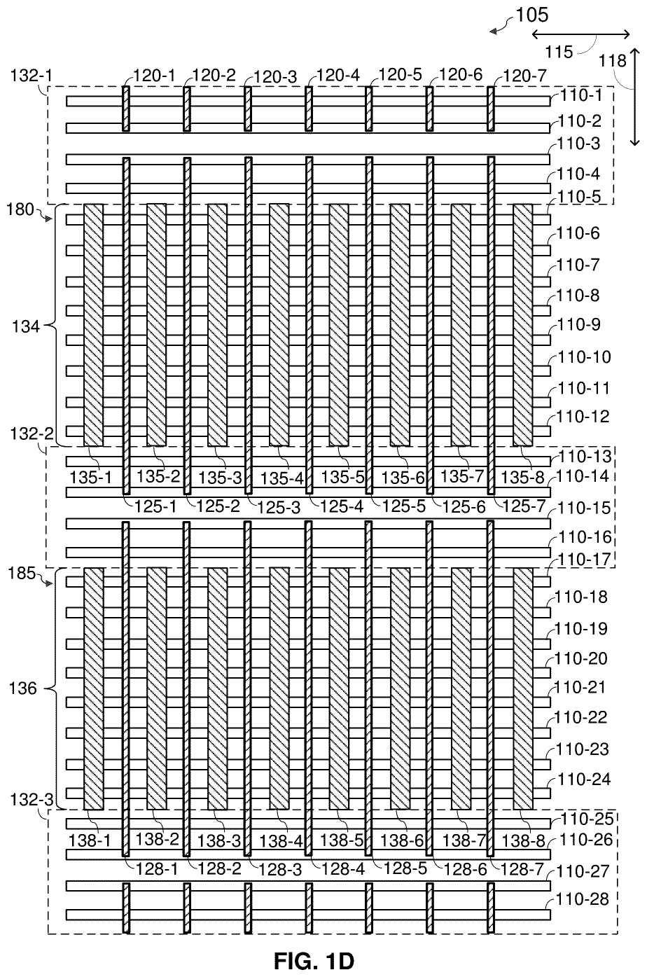

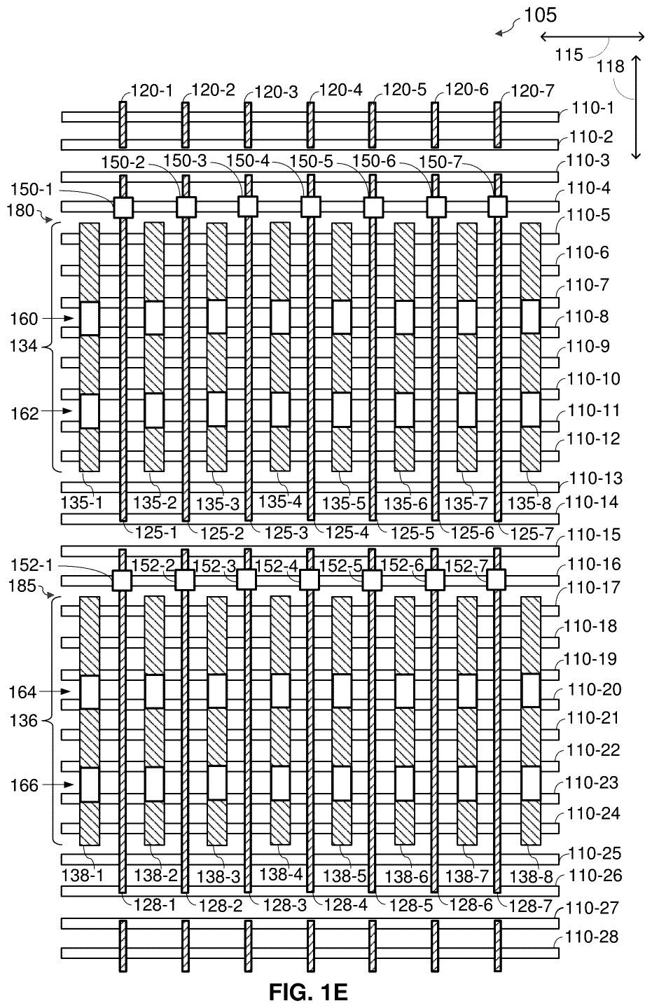

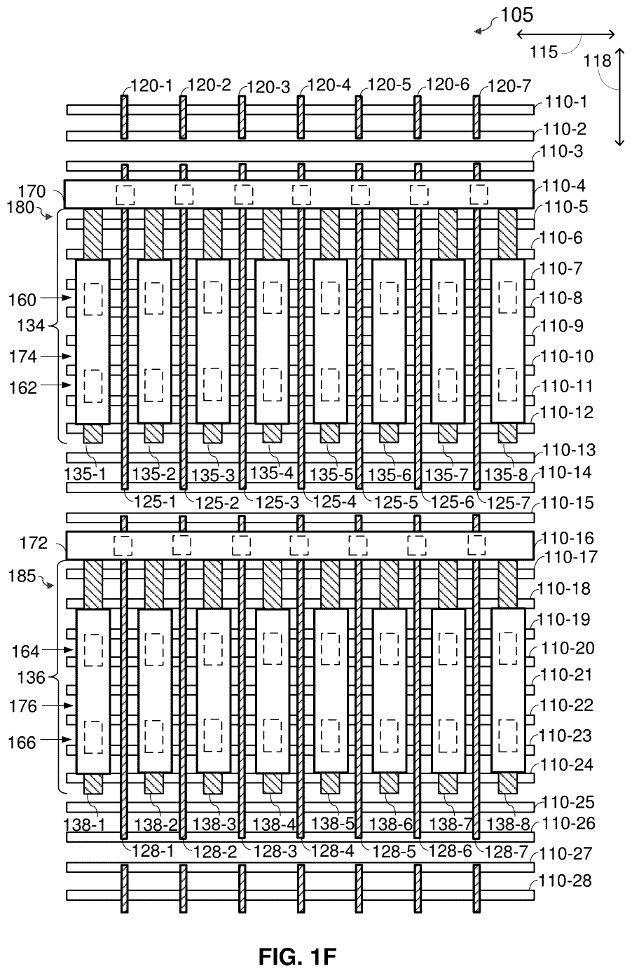

FIGS. 1A to 1F show top views of various layers of a semiconductor die 105 including a first transistor 180 and a second transistor 185 according to certain aspects of the present disclosure. Although two transistors 180 and 185 are shown in FIGS. 1A to 1E, it is to be appreciated that the die 105 may include thousands to billions of transistors. In the example shown in FIGS. 1A to 1F, each of the transistors 180 and 185 is a Fin Field Effect Transistor (FinFET). However, it is to be appreciated that exemplary layout techniques disclosed herein may also be applied to planar transistor technologies, nanowire technologies, nanosheet technologies, gate-all-around FET technologies, etc.

FIG. 1A shows an example of fins 110-1 to 110-28 formed on the substrate of the die 105. The fins 110-1 to 110-28 run parallel to each other, and extend in a first direction 115. The first direction 115 is a lateral direction in that the first direction 115 runs horizontally with respect to the substrate of the die 105. The fins 110-1 to 110-28 may be evenly spaced apart, as shown in the example in FIG. 1A. However, it is to be appreciated that this need not be the case in some implementations. The fins 110-1 to 110-28 may be made of silicon, silicon germanium, silicon carbon, or any combination thereof. Although twenty-eight fins 110-1 to 110-28 are shown in FIG. 1A, it is to be appreciated that the die 105 may include a much larger number of fins.

FIG. 1A also shows gates 120-1 to 120-7 formed over the fins 110-1 to 110-28, and running perpendicular to the fins 110-1 to 110-28. Each of the gates 120-1 to 120-7 extends in a second direction 118, in which the second direction 118 is perpendicular to the first direction 115. The second direction 118 is a lateral direction in that the second direction 118 runs horizontally with respect to the substrate of the die 105. The gates 120-1 to 120-7 may be evenly spaced apart, as shown in the example in FIG. 1A. However, it is to be appreciated that this need not be the case in some implementations. Although seven gates 120-1 to 120-7 are shown in the example in FIG. 1A, it is to be appreciated that the die 105 may include a much larger number of gates.

The die 105 may also include a thin dielectric layer (not shown) interposed between the fins 110-1 to 110-28 and the gates 120-1 to 120-7. However, it is to be appreciated that the present disclosure is not limited to this example.

FIG. 1B shows an example in which portions of the gates 120-1 to 120-7 are cut using a photolithographic and etching process. The cuts 122-1, 122-2, and 122-3 in the gates 120-1 to 120-7 may also be referred to as cut layers. The cut 122-2 in the middle of FIG. 1B separates a first portion 124 of the gates 120-1 to 120-7 from a second portion 126 of the gates 120-1 to 120-7. The first portion 124 of the gates 120-1 to 120-7 is between cuts 122-1 and 122-2, and the second portion 126 of the gates 120-1 to 120-7 is between cuts 122-2 and 122-3. As discussed further below, the first portion 124 of the gates 120-1 to 120-7 provides the gates 125-1 to 125-7 of the first transistor 180, and the second portion 126 of the gates 120-1 to 120-7 provides the gates 128-1 to 128-7 of the second transistor 185.

FIG. 1C shows source/drain contact layers 130-1 to 130-8 formed on the fins 110-1 to 110-28. As used herein, the term “source/drain” means source or drain. Each of the source/drain contact layers 130-1 to 130-8 may include one conductive material or multiple conductive materials (e.g., copper and/or another metal). As shown in FIG. 1C, the source/drain contact layers 130-1 to 130-8 run parallel to each other, and extend in the second direction 118. In the example in FIG. 1C, each of the gates 120-1 to 120-7 is between two of the source/drain contact layers 130-1 to 130-8.

FIG. 1D shows an example in which portions of the source/drain contact layers 130-1 to 130-8 are cut using a photolithographic and etching process. The cuts 132-1, 132-2, and 132-3 in the source/drain contact layers 130-1 to 130-8 may also be referred to as cut layers. The cut 132-2 in the middle of FIG. 1D separates a first portion 134 of the source/drain contact layers 130-1 to 130-8 from a second portion 136 of the source/drain contact layers 130-1 to 130-8. The first portion 134 of the source/drain contact layers 130-1 to 130-8 is between cuts 132-1 and 132-2, and the second portion 136 of the source/drain contact layers 130-1 to 130-8 is between cuts 132-2 and 132-3. As discussed further below, the first portion 134 of the source/drain contact layers 130-1 to 130-8 provides the source/drain contact layers 135-1 to 135-8 of the first transistor 180, and the second portion 136 of the source/drain contact layers 130-1 to 130-8 provides the source/drain contact layers 138-1 to 138-8 of the second transistor 185.

In the example in FIG. 1D, each of the source/drain contact layers 135-1 to 135-8 of the first transistor 180 extends over the fins 110-5 to 110-12 and is electrically coupled to the fins 110-5 to 110-12. The portions of the fins 110-5 to 110-12 under the source/drain contact layers 135-1, 135-3, 135-5, and 135-7 may serve as the source of the first transistor 180 and the portions of the fins 110-5 to 110-12 under the source/drain contact layers 135-2, 135-4, 135-6, and 135-8 may serve as the drain of the first transistor 180, or vice versa. The portions of the fins 110-5 to 110-12 under the gates 125-1 to 125-7 serve as the channel of the first transistor 180, in which the conductivity of the channel is controlled by the voltage applied to the gates 125-1 to 125-7.

In the example in FIG. 1D, each of the source/drain contact layers 138-1 to 138-8 of the second transistor 185 extends over the fins 110-17 to 110-24 and is electrically coupled to the fins 110-17 to 110-24. The portions of the fins 110-17 to 110-24 under the source/drain contact layers 138-1, 138-3, 138-5, and 138-7 may serve as the source of the second transistor 185 and the portions of the fins 110-17 to 110-24 under the source/drain contact layers 138-2, 138-4, 138-6, and 138-8 may serve as the drain of the second transistor 185, or vice versa. The portions of the fins 110-17 to 110-24 under the gates 128-1 to 128-7 serve as the channel of the second transistor 185, in which the conductivity of the channel is controlled by the voltage applied to the gates 128-1 to 128-7.

FIG. 1E shows gate vias 150-1 to 150-7 distributed on the gates 125-1 to 125-7 of the first transistor 180. The gate vias 150-1 to 150-7 are aligned with each other along the first direction 115, in which each of the gate vias 150-1 to 150-7 is electrically coupled to a respective one of the gates 125-1 to 125-7.

FIG. 1E also shows gate vias 152-1 to 152-7 distributed on the gates 128-1 to 128-7 of the second transistor 185. The gate vias 152-1 to 152-7 are aligned with each other along the first direction 115, in which each of the gate vias 152-1 to 152-7 is electrically coupled to a respective one of the gates 128-1 to 128-7.

FIG. 1E also shows a first row of source/drain vias 160 and a second row of source/drain vias 162 distributed on the source/drain contact layers 135-1 to 135-8 of the first transistor 180. The first row of source/drain vias 160 is spaced apart from the second row of source/drain vias 162 in the second direction 118. The source/drain vias 160 are aligned with each other along the first direction 115, in which each of the source/drain vias 160 is electrically coupled to a respective one of the source/drain contact layers 135-1 to 135-8. The source/drain vias 162 are aligned with each other along the first direction 115, in which each of the source/drain vias 162 is electrically coupled to a respective one of the source/drain contact layers 135-1 to 135-8. In this example, the source/drain contact layers 135-1 to 135-8 provide local routing between the fins 110-5 to 110-12 and the source/drain vias 160 and 162.

FIG. 1E also shows a third row of source/drain vias 164 and a fourth row of source/drain vias 166 distributed on the source/drain contact layers 138-1 to 138-8 of the second transistor 185. The third row of source/drain vias 164 is spaced apart from the fourth row of source/drain vias 166 in the second direction 118. The source/drain vias 164 are aligned with each other along the first direction 115, in which each of the source/drain vias 164 is electrically coupled to a respective one of the source/drain contact layers 138-1 to 138-8. The source/drain vias 166 are aligned with each other along the first direction 115, in which each of the source/drain vias 166 is electrically coupled to a respective one of the source/drain contact layers 138-1 to 138-8. In this example, the source/drain contact layers 138-1 to 138-8 provide local routing between the fins 110-17 to 110-24 and the source/drain vias 164 and 166.

FIG. 1F shows a first gate metal layer 170 formed on the gate vias 150-1 to 150-7 of the first transistor 180 and extending in the first direction 115. Each of the gate vias 150-1 to 150-7 is disposed between the first gate metal layer 170 and a respective one of the gates 125-1 to 125-7. The gate vias 150-1 to 150-7 are shown with dashed lines in FIG. 1F since they are under the first gate metal layer 170. Each of the gate vias 150-1 to 150-7 electrically couples the respective one of the gates 125-1 to 125-7 to the first gate metal layer 170. Note that the reference numbers of the gate vias 150-1 to 150-7 are not shown in FIG. 1F for case of illustration.

FIG. 1F also shows a second gate metal layer 172 formed on the gate vias 152-1 to 152-7 of the second transistor 185 and extending in the first direction 115. Each of the gate vias 152-1 to 152-7 is disposed between the second gate metal layer 172 and a respective one of the gates 128-1 to 128-7. The gate vias 152-1 to 152-7 are shown with dashed lines in FIG. 1F since they are under the second gate metal layer 172. Each of the gate vias 152-1 to 152-7 electrically couples the respective one of the gates 128-1 to 128-7 to the second gate metal layer 172. Note that the reference numbers of the gate vias 152-1 to 152-7 are not shown in FIG. 1F for case of illustration.

In certain aspects, the gate metal layers 170 and 172 are formed from a first metal layer (e.g., using a photolithographic and etching process). The first metal layer may be a metal-1 (M1) layer used for routing. Other metal layers on the die 105 located above the M1 layer with respect to the substrate may be designated with higher numbers, in which a metal-2 (M2) layer is above the M1 layer, a metal-3 (M3) layer is above the M2 layer, and so forth. It is to be appreciated that the present disclosure is not limited to this example. It is also to be appreciated that, in some cases, the first metal layer may be referred to as a metal-0 (M0) layer for a convention in which the numerical designation for metal layers starts with zero.

FIG. 1F also shows source/drain metal layers 174 running parallel to each other. Each of the source/drain metal layers 174 extends in the second direction 118 over a portion of a respective one of the source/drain contact layers 135-1 to 135-8 of the first transistor 180. Also, each of the source/drain metal layers 174 is electrically coupled to the respective one of the source/drain contact layers 135-1 to 135-8 by a respective one of the source/drain vias 160 and a respective one of the source/drain vias 162. Thus, each of the source/drain metal layers 174 is electrically coupled to the respective one of the source/drain contact layers 135-1 to 135-8 through two vias in this example.

FIG. 1F also shows source/drain metal layers 176 running parallel to each other. Each of the source/drain metal layers 176 extends in the second direction 118 over a portion of a respective one of the source/drain contact layers 138-1 to 138-8 of the second transistor 185. Also, each of the source/drain metal layers 176 is electrically coupled to the respective one of the source/drain contact layers 138-1 to 138-8 by a respective one of the source/drain vias 164 and a respective one of the source/drain vias 166. Thus, each of the source/drain metal layers 176 is electrically coupled to the respective one of the source/drain contact layers 138-1 to 138-8 through two vias in this example.

The source/drain metal layers 174 and 176 may be formed from the first metal layer (e.g., M1 layer) discussed above (e.g., using a photolithographic and etching process). Alternatively, the source/drain metal layers 174 and 176 may be formed from a metal layer that is different from the first metal layer.

In the example in FIG. 1F, each of the first transistor 180 and the second transistor 185 has the same structure and same orientation. The first transistor 180 and the second transistor 185 have the same orientation in the sense that the respective gate metal layer 170 and 172 is located above the respective source/drain metal layers 174 and 174 in the top view shown in FIG. 1F. The structure of each of the first transistor 180 and the second transistor 185 may be repeated on the die 105 to form an array of transistors on the die 105.

Multiple instances of the transistors 180 and 185 may be used as switches (e.g., in an adaptive power multiplexer) to control power to one or more circuits. In this example, it is desirable for the transistors 180 and 185 to have low on-resistance to reduce the IR voltage drop across the transistors. As used herein, “on-resistance” is the resistance of a transistor when the transistor is turned on. Adding more transistors in parallel reduces the on-resistance, but at the expense of more area on the die 105. As technology nodes become smaller, the via resistance continues to dominate the on-resistance of the transistors. In many cases, a transistor may be limited to only one or two vias per source/drain contact layer, which increases via resistance. In the example shown in FIG. 1F, each of the transistors 180 and 185 has two vias per source/drain contact layer.

To address the above challenge, aspects of the present disclosure provide layout techniques that increase the lengths of the source/drain contact layers compared with the layout technique illustrated in FIGS. 1A to 1F. The increased lengths of the source/drain contact layers allow more vias per source/drain contact layer, which reduces via resistance by providing more parallel resistive paths through the vias, as discussed further below.

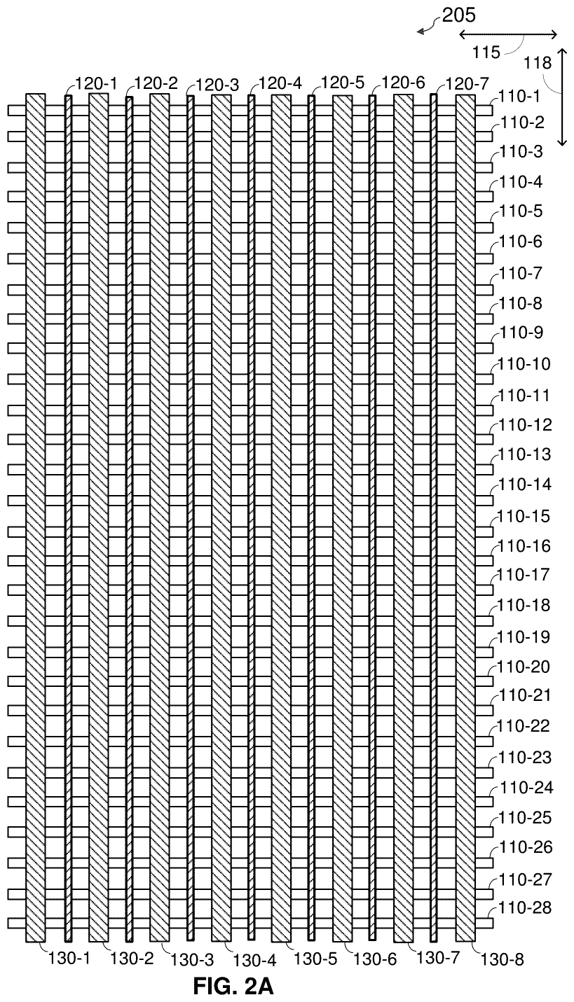

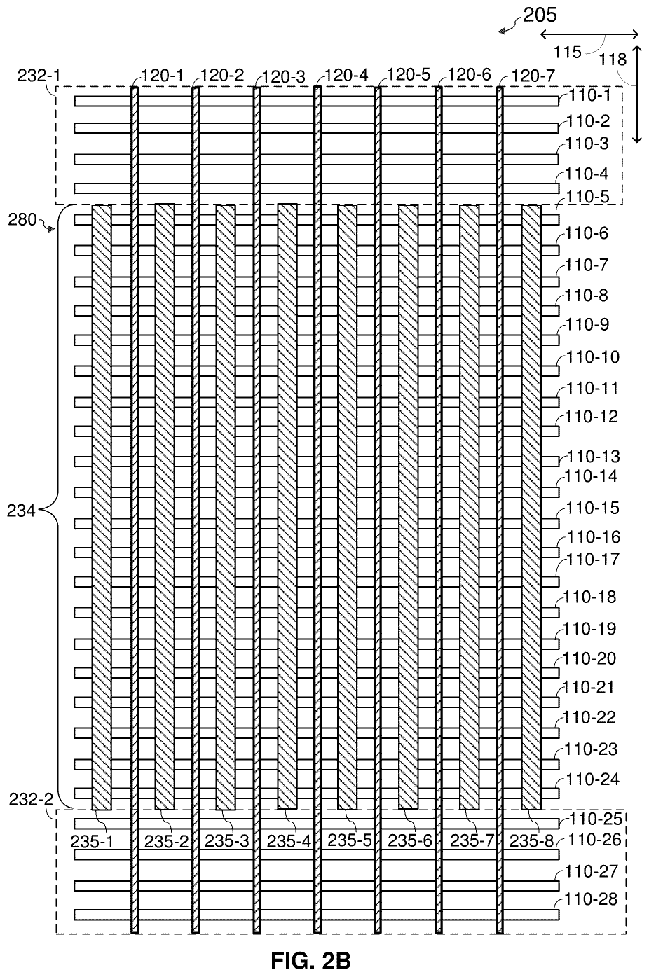

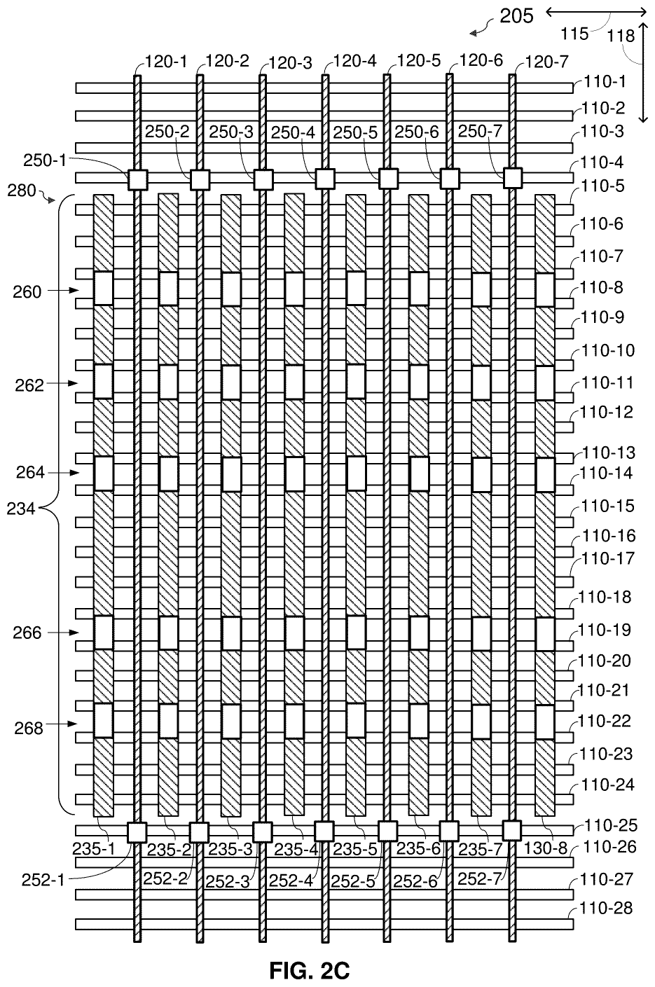

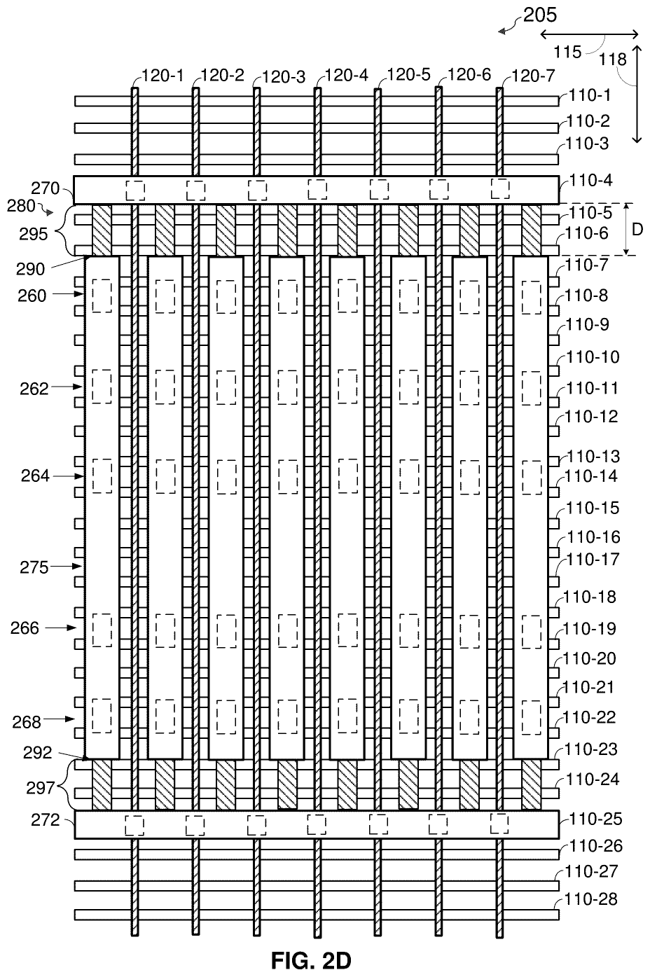

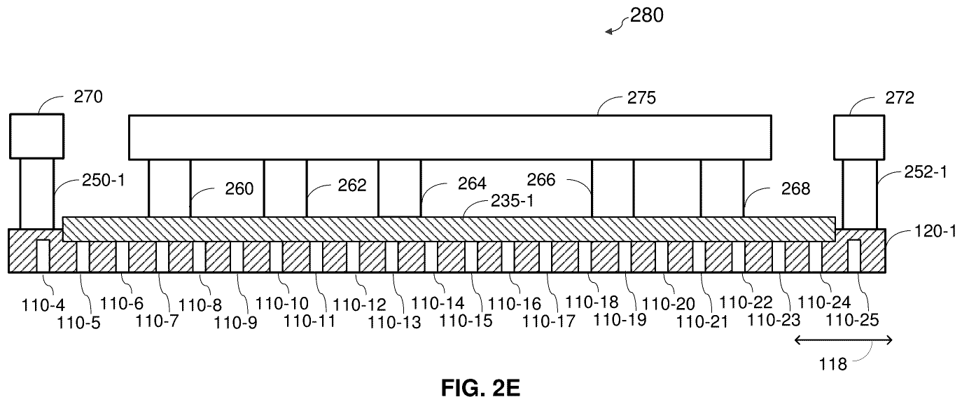

FIGS. 2A to 2E show top views of various layers of a semiconductor die 205 including a transistor 280 according to certain aspects of the present disclosure. Although one transistor 280 is shown in FIGS. 2A to 2E, it is to be appreciated that the die 205 may include thousands to billions of transistors. In the example shown in FIGS. 2A to 2E, the transistor 280 is a FinFET. However, it is to be appreciated that exemplary layout techniques disclosed herein may also be applied to planar transistor technologies, nanowire technologies, nanosheet technologies, gate-all-around FET technologies, etc. As discussed further below, the exemplary layout shown in FIGS. 2A to 2E reduces on-resistance compared with the layout shown in FIGS. 1A to 1F.

FIG. 2A shows the fins 110-1 to 110-28 formed on the substrate of the die 205. As discussed above, the fins 110-1 to 110-28 run parallel to each other, and extend in the first direction 115. In the example in FIG. 2A, the fins 110-1 to 110-28 are evenly spaced apart on the die 205. However, it is to be appreciated that this need not be the case in some implementations. Although twenty-eight fins 110-1 to 110-28 are shown in FIG. 2A, it is to be appreciated that the die 205 may include a much larger number of fins.

FIG. 2A also shows the gates 120-1 to 120-7 formed over the fins 110-1 to 110-28. As discussed above, the gates 120-1 to 120-7 extend in the second direction 118 and run perpendicular to the fins 110-1 to 110-28. In the example in FIG. 2A, the gates 120-1 to 120-7 are evenly spaced apart. However, it is to be appreciated that this need not be the case in some implementations. Although seven gates 120-1 to 120-7 are shown in the example in FIG. 2A, it is to be appreciated that the die 205 may include a much larger number of gates.

The die 205 may also include a thin dielectric layer (not shown) interposed between the fins 110-1 to 110-28 and the gates 120-1 to 120-7. However, it is to be appreciated that the present disclosure is not limited to this example.

FIG. 2A also shows the source/drain contact layers 130-1 to 130-8 formed over the fins 110-1 to 110-28. As discussed above, the source/drain contact layers 130-1 to 130-8 run parallel to each other and extend in the second direction 118. In the example in FIG. 2A, each of the gates 120-1 to 120-7 is between two of the source/drain contact layers 130-1 to 130-8. In other words, the gates 120-1 to 120-7 and the source/drain contact layers 130-1 to 130-8 are interleaved. In the example in FIG. 2A, the gates 120-1 to 120-7 and the source/drain contact layers 130-1 to 130-8 are interleaved in the first direction 115 in which the die 205 alternates between gate and source/drain contact layer in the first direction 115. Each of the source/drain contact layers 130-1 to 130-8 may include one conductive material or multiple conductive materials (e.g., in multiple layers where each of the layers may include a respective one of the conductive materials). As used herein, a “source/drain contact layer” provides an electrically conductive interface to one or more fins. In certain aspects, a “source/drain contact layer” may be a middle-end-of-line (MEOL) layer that provides an electrically conductive interface between one or more fins in a front-end-of-line (FEOL) and one or more metal layers (e.g., M1 layer) in a back-end-of-line (BEOL).

FIG. 2B shows an example in which portions of the source/drain contact layers 130-1 to 130-8 are cut using a photolithographic and etching process. The cuts 232-1 and 232-2 in the source/drain contact layers 130-1 to 130-8 may also be referred to as cut layers. The cuts 232-1 and 232-2 may correspond to the cuts 132-1 and 132-3, respectively, shown in FIG. 1D. In this example, the middle cut 132-2 shown in FIG. 1D is removed. The removal of the middle cut 132-2 allows the source/drain contact layers 130-1 to 130-8 to be contiguous (i.e., continuous) between the cuts 232-1 and 232-2. The portion 234 of the source/drain contact layers 130-1 to 130-8 between the cuts 231-1 and 232-2 provides the source/drain contact layers 235-1 to 235-8 of the transistor 280. As shown in FIG. 2B, the removal of the middle cut 132-2 significantly increases the length of each of the source/drain contact layers 235-1 to 235-8 compared with the length of each of the source/drain contact layers 135-1 to 135-8 and 138-1 to 138-8 in FIG. 1D. As discussed further below, the increased length of each of the source/drain contact layers 235-1 to 235-8 allows more vias to be formed on each of the source/drain contact layers 235-1 to 235-8, which provides more parallel resistive paths through the vias for lower resistance.

Also, in the example in FIG. 2B, the cuts 122-1, 122-2, and 122-3 in the gates 120-1 to 120-7 shown in FIG. 1B are removed, allowing the gates 120-1 to 120-7 to run contiguously (i.e., continuously) across the fins 110-1 to 110-28. In one example, the gates 120-1 to 120-7 may run contiguously across an array of transistors with cuts in the gates 120-1 to 120-7 located at the boundaries of the array of transistors. In another example, the gates 120-1 to 120-7 may be cut at the cuts 122-1 and 122-3 shown in FIG. 1B with the middle cut 122-2 removed. In both examples, the middle cut 122-2 of the gates 120-1 to 120-7 is removed.

In the example in FIG. 2B, each of the source/drain contact layers 235-1 to 235-8 extends over the fins 110-5 to 110-24 and is electrically coupled to the fins 110-5 to 110-24. The portions of the fins 110-5 to 110-24 under the source/drain contact layers 235-1, 235-3, 235-5, and 235-7 may serve as the source of the transistor 280 and the portions of the fins 110-5 to 110-24 under the source/drain contact layers 235-2, 235-4, 235-6, and 235-8 may serve as the drain of the transistor 280, or vice versa. The portions of the fins 110-5 to 110-24 under the gates 120-1 to 120-7 serve as the channel of the transistor 280, in which the conductivity of the channel is controlled by the voltage applied to the gates 120-1 to 120-7.

FIG. 2C also shows a first row of source/drain vias 260, a second row of source/drain vias 262, a third row of source/drain vias 264, a fourth row of source/drain vias 266, and a fifth row of source/drain vias 268 distributed on the source/drain contact layers 235-1 to 235-8. The row of source/drain vias 260, 262, 264, 266, and 268 are spaced apart in the second direction 118, as shown in FIG. 2C. The vias 260 are aligned with each other along the first direction 115, in which each of the source/drain vias 260 is electrically coupled to a respective one of the source/drain contact layers 235-1 to 235-8. The vias 262 are aligned with each other along the first direction 115, in which each of the vias 262 is electrically coupled to a respective one of the source/drain contact layers 235-1 to 235-8. The vias 264 are aligned with each other along the first direction 115, in which each of the vias 264 is electrically coupled to a respective one of the source/drain contact layers 235-1 to 235-8. The vias 266 are aligned with each other along the first direction 115, in which each of the vias 266 is electrically coupled to a respective one of the source/drain contact layers 235-1 to 235-8. The vias 268 are aligned with each other along the first direction 115, in which each of the source/drain vias 268 is electrically coupled to a respective one of the source/drain contact layers 235-1 to 235-8. Thus, in this example, a subset of five of the vias 260, 262, 264, 266, and 268 is distributed on each of the source/drain contact layers 235-1 to 235-8. Each of the vias 260, 262, 264, 266, and 268 may include one conductive material or multiple conductive materials (e.g., in multiple layers). In this example, the source/drain contact layers 235-1 to 235-8 provide local routing between the fins 110-5 to 110-24 and the source/drain vias 260, 262, 264, 266, and 268.

In this example, the removal of the middle cut 132-2 shown in FIG. 1D provides additional area on the source/drain contact layers 235-1 to 235-8 for the placement of an additional row of source/drain vias 264 compared with the layout in FIG. 1E. The additional row of source/drain vias 264 reduces the on-resistance of the transistor 280, as discussed further below.

FIG. 2C also shows gate vias 250-1 to 250-7 distributed on the gates 120-1 to 120-7. Each of the gate vias 250-1 to 250-7 may include one conductive material or multiple conductive materials (i.e., in multiple layers). The gate vias 250-1 to 250-7 are aligned with each other along the first direction 115, in which each of the gate vias 250-1 to 250-7 is electrically coupled to a respective one of the gates 120-1 to 120-7. The gate vias 250-1 to 250-7 are located above the source/drain contact layers 235-1 to 235-8 in the second direction 118 shown in FIG. 2D.

FIG. 2C also shows gate vias 252-1 to 252-7 distributed on the gates 120-1 to 120-7. Each of the gate vias 252-1 to 252-7 may include one conductive material or multiple conductive materials (e.g., in multiple layers). The gate vias 252-1 to 252-7 are aligned with each other along the first direction 115, in which each of the gate vias 252-1 to 252-7 is electrically coupled to a respective one of the gates 120-1 to 120-7. The gate vias 252-1 to 252-7 are located below the source/drain contact layers 235-1 to 235-8 in the second direction 118 shown in FIG. 2C. In contrast, the gate vias 152-1 to 152-7 shown in FIG. 1E are located above the source/drain contact layers 138-1 to 138-7 in the second direction 118. Thus, the orientation of the gate vias 252-1 to 252-7 and the source/drain contact layers 235-1 to 235-8 is flipped with respect to the orientation of the gate vias 152-1 and 152-7 and the source/drain contact layers 138-1 to 138-7. The flipped orientation moves the gate vias 252-1 to 252-7 farther away from the gate vias 250-1 to 250-7, which allows each of the source/drain contact layers 235-1 to 235-7 to extend over a substantially longer length between the gate vias 250-1 to 250-7 and the gate vias 252-1 to 252-7. As discussed above, the increased length of each of the source/drain contact layers 235-1 to 235-8 allows more vias per source/drain contact layer 235-1 to 235-8, which provides more parallel resistive paths through the vias for lower resistance.

As shown in FIG. 2C, the flipped orientation results in the source/drain contact layers 235-1 to 235-8 being located between the gate vias 250-1 to 250-7 on the top and the gate vias 252-1 to 252-7 on the bottom in the second direction 118. The gate vias 250-2 to 250-7 may also be referred to as first gate vias and the gate vias 252-1 to 252-7 may also be referred to as second gate vias.

FIG. 2D shows a first gate metal layer 270 formed on the gate vias 250-1 to 250-7 and extending in the first direction 115. Each of the gate vias 250-1 to 250-7 is disposed between the first gate metal layer 270 and a respective one of the gates 120-1 to 120-7. The gate vias 250-1 to 250-7 are shown with dashed lines in FIG. 2D since they are under the first gate metal layer 270. Each of the gate vias 250-1 to 250-7 electrically couples the respective one of the gates 120-1 to 120-7 to the first gate metal layer 270. Note that the reference numbers of the gate vias 250-1 to 250-7 are not shown in FIG. 2D for ease of illustration.

FIG. 2D also shows a second gate metal layer 272 formed on the gate vias 252-1 to 252-7 and extending in the first direction 115. Each of the gate vias 252-1 to 252-7 is disposed between the second gate metal layer 272 and a respective one of the gates 120-1 to 120-7. The gate vias 252-1 to 252-7 are shown with dashed lines in FIG. 2D since they are under the second gate metal layer 272. Each of the gate vias 252-1 to 252-7 electrically couples the respective one of the gates 120-1 to 120-7 to the second gate metal layer 272. Note that the reference numbers of the gate vias 252-1 to 252-7 are not shown in FIG. 2D for case of illustration. In certain aspects, the gate metal layers 270 and 272 are formed from the first metal layer (e.g., M1 layer) discussed above (e.g., using a photolithographic and etching process).

FIG. 2D also shows source/drain metal layers 275 running parallel to each other. Each of the source/drain metal layers 275 extends in the second direction 118 over at least a portion of a respective one of the source/drain contact layers 235-1 to 235-8. Also, each of the source/drain metal layers 275 is electrically coupled to the respective one of the source/drain contact layers 235-1 to 235-8 by a respective one of the vias 260, a respective one of the vias 262, a respective one of the vias 264, a respective one of the vias 266, and a respective one of the vias 268.

Thus, each of the source/drain metal layers 275 is electrically coupled to the respective one of the source/drain contact layers 235-1 to 235-8 through five vias in this example. In other words, in this example, there are five vias per source/drain contact layer 235-1 to 235-8, which provide five parallel resistive paths between each of the source/drain contact layers 235-1 to 235-8 and the respective source/drain metal layer 275 for lower resistance. In contrast, there are only two vias per source/drain contact layer 135-1 to 135-8 and 138-1 to 138-8 in the layout shown in FIG. 1F, resulting in fewer parallel paths and therefore higher resistance.

In addition, each of the source/drain metal layers 275 is substantially longer than each of the source/drain metal layers 174 and 176 shown in FIG. 1F. This is because the orientation of the gate vias 252-1 to 252-7 and the source/drain contact layers 235-1 to 235-8 is flipped with respect to the orientation of the gate vias 152-1 and 152-7 and the source/drain contact layers 138-1 to 138-7 in FIG. 1F. The flipped orientation moves the second gate metal layer 172 from the middle of the layout shown in FIG. 2C toward the bottom of the layout shown in FIG. 2C. This allows the source/drain metal layers 275 to extend contiguously (i.e., continuously) over the source/drain contact layers 235-1 to 235-7 without obstruction from the second gate metal layer 172.

The longer lengths of the source/drain metal layers 275 also allows more vias to be placed between the source/drain metal layers 275 and higher metal layers (not shown). For example, the source/drain metal layers 275 may be formed from the M1 layer and the higher metal layers may be formed from the M2 layer (e.g., using a photolithographic and etching process). The larger number of vias provide more parallel paths between the source/drain metal layers 275 and the higher metal layers, which further lowers resistance. The higher metal layers may provide routing between the transistor 280 and a supply rail and/or routing between the transistor 280 and one or more circuits.

As shown in FIG. 2D, the first gate metal layer 270 and the second gate metal layer 272 are located on opposite ends of the source/drain metal layers 275. In this example, a first end 290 of each of the source/drain metal layers 275 is spaced apart from the first gate metal layer 270 by a distance of D. This may be done to maintain a minimum space between the source/drain metal layers 275 and the first gate metal layer 270. The minimum space may be a constraint imposed by the process technology used to fabricate the transistor 280 (e.g., to prevent metal layers from unintentionally shorting due to process variation). As shown in FIG. 2D, the fins 110-5 and 110-6 are located within the space between the source/drain metal layers 275 and the first gate metal layer 270, and therefore do not overlap the source/drain metal layers 275. In this example, a first portion 295 of each the source/drain contact layers 235-1 to 235-8 extends pass the first end 290 of the respective source/drain metal layer 275 and over the fins 110-5 and 110-6. The extension of the source/drain contact layers 235-1 to 235-8 over the fins 110-5 and 110-6 allow the fins 110-5 and 110-6 to be part of the active region (also referred to as the diffusion region) of the transistor 280 while maintaining the minimum space between the source/drain metal layers 275 and the first gate metal layer 270. In this example, the source/drain contact layers 235-1 to 235-8 provide routing between the fins 110-5 and 110-6 and the vias 260, 262, 264, 266, and 268, which are electrically coupled to the source/drain metal layers 275.

Similarly, a second end 292 of each of the source/drain metal layers 275 is spaced apart from the second gate metal layer 272 (e.g., by the distance of D or a different distance). The first end 290 and the second end 292 of each of the source/drain metal layers 275 are opposite ends of the source/drain metal layer. As shown in FIG. 2D, the fins 110-23 and 110-24 are located within the space between the source/drain metal layers 275 and the second gate metal layer 272, and therefore do not overlap the source/drain metal layers 275. In this example, a second portion 297 of each of the source/drain contact layers 235-1 to 235-8 extends pass the second end 292 of the respective source/drain metal layers 275 and over the fins 110-23 and 110-24. The extension of the source/drain contact layers 235-1 to 235-8 over the fins 110-23 and 110-24 allow the fins 110-23 and 110-24 to be part of the active region of the transistor 280 while maintaining the minimum space between the source/drain metal layers 275 and the second gate metal layer 272. In this example, the source/drain contact layers 235-1 to 235-8 provide routing between the fins 110-23 and 110-24 and the vias 260, 262, 264, 266, and 268, which are electrically coupled to the source/drain metal layers 275.

FIG. 2E shows a side view of the transistor 280 shown in FIG. 2D. Each of the gates 120-1 to 120-8 may wrap around three or more sides of each of the fins 110-1 to 110-24 (e.g., wrap around the top side and two opposite sidewalls of each of the fins 110-1 to 110-24). This increases the surface area between the gates 120-1 to 120-7 and the fins 110-1 to 110-24, providing improved electrical control over the channel conductance of the transistor 280. It is to be appreciated that only the gate 120-1 is visible in the side view shown in FIG. 2E. Note that the first direction 115 is perpendicular to the side view shown in FIG. 2E.

Although each of the fins 110-4 to 110-24 is shown as having a rectangular cross section (i.e., profile) in the example in FIG. 2E, it is to be understood that each of the fins 110-1 to 110-24 may have another cross-sectional shape. For example, each of the fins 110-1 to 110-24 may have a tapered cross section, in which the fin is thicker at the base than the top.

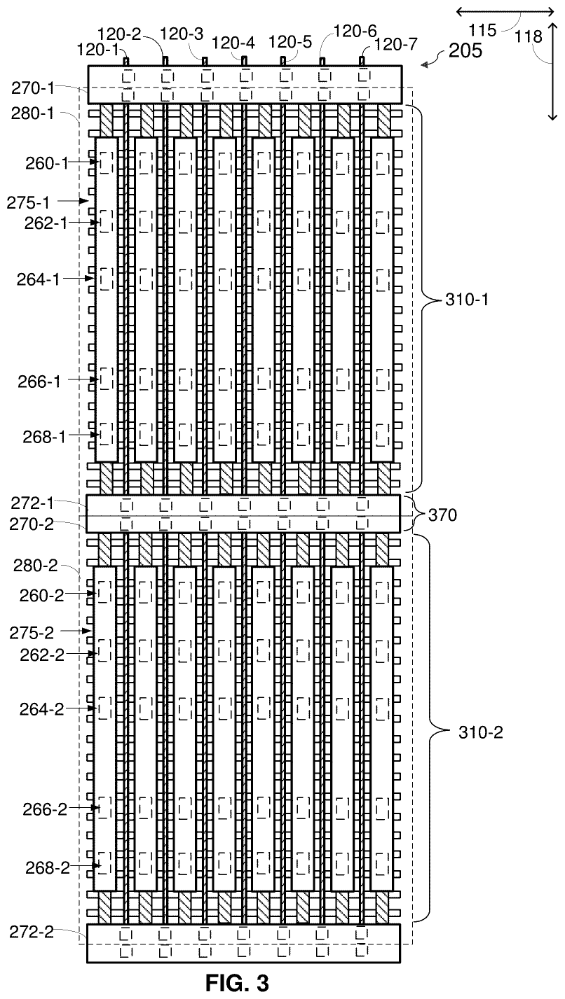

In certain aspects, multiple instances of the transistor 280 may be fabricated on the die 205 to form an array of transistors. In this regard, FIG. 3 shows an example in which the die 205 includes a first transistor 280-1 and a second transistor 280-2. In this example, each of the first transistor 280-1 and the second transistor 280-2 is a separate instance (i.e., copy) of the exemplary transistor 280 discussed above with reference to FIGS. 2A to 2E. Accordingly, the description of the transistor 280 according to various aspects is applicable to each of the first transistor 280-1 and the second transistor 280-2. In FIG. 3, the reference numbers for the first transistor 280-1 include the suffix one and the reference numbers for the second transistor 280-2 include the suffix two.

In this example, the gates 120-1 to 120-7 extend contiguously (i.e., continuously) across the first transistor 280-1 and the second transistor 280-2 with no cuts in the gates 120-1 to 120-7 between the first transistor 280-1 and the second transistor 280-2. Although two transistors 280-1 and 280-2 are shown in FIG. 3, it is to be appreciated that the gates 120-1 to 120-7 may extend contiguously (i.e., continuously) across more than two transistors.

In the example in FIG. 3, the second gate metal layer 272-1 of the first transistor 280-1 is adjacent to the first gate metal layer 270-2 of the second transistor 280-2. In one example, the gate metal layers 272-1 and 270-2 may be merged into a common gate metal layer 370 with two rows of gate vias disposed between the common gate metal layer 370 and the gates 120-1 to 120-7. In this example, the die 205 includes two gate vias disposed between the common gate metal layer 370 and each of the gates 120-1 to 120-7. Thus, in this example, the common gate metal layer 370 is electrically coupled to each of the gates 120-1 to 120-7 by two parallel gate vias. The two parallel gate vias per gate 120-1 to 120-7 lowers the resistance between each of the gates 120-1 to 120-7 and the common gate metal layer 370 by providing parallel resistive paths. Note that the individual gate vias are shown with dashed lines since the gate vias are under the common gate metal layer 370. In this example, the gates 120-1 to 120-7 extend contiguously under the common gate metal layer 370. It is to be appreciated that the present disclosure is not limited to this example, and that the gate metal layers 272-1 and 270-2 may be separated in some implementations.

The fins 310-1 in the first transistor 280-1 may be referred to as first fins and the fins 310-2 in the second transistor 280-2 may be referred to as second fins. The fins in each of the transistors 280-1 to 280-2 may correspond to the respective fins 110-5 to 110-24 shown in FIG. 2D.

As shown in FIG. 3, the source/drain contact layers and the source/drain metal layers 275-1 of the first transistor 280-1 are between the gate metal layer 270-1 and the common gate metal layer 370 in the second direction 118. The source/drain contact layers and the source/drain metal layers 275-2 of the second transistor 280-2 are between the common gate metal layer 370 and the gate metal layer 272-2. The source/drain contact layers of the each of the transistors 280-1 to 280-2 may correspond to the respective source/drain contact layers 235-1 to 235-8 shown in FIG. 2D. In this example, the gate metal layer 270-1, the gate metal layer 370, and the gate metal layer 272-2 may be referred to as a first gate metal layer, a second gate metal layer, and a third gate metal layer, respectively.

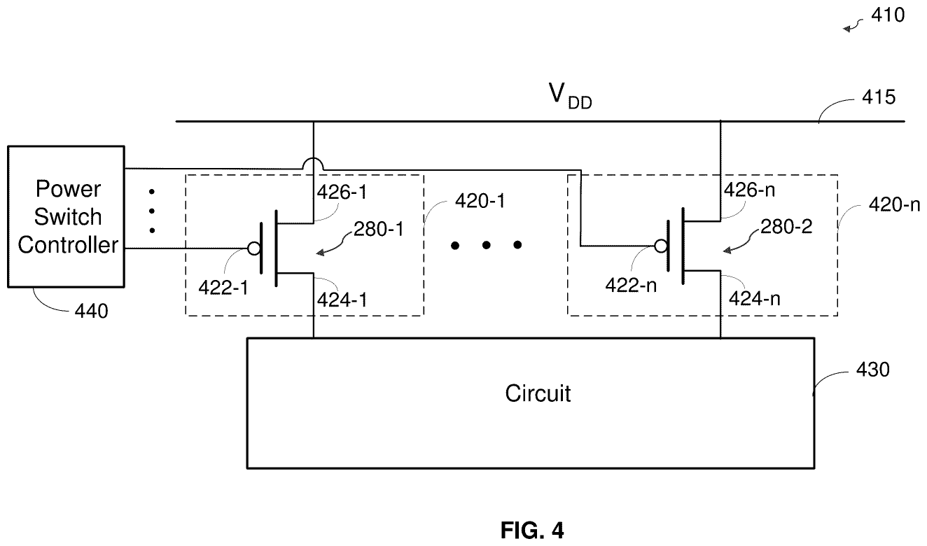

The transistor 280 may be used as a power switch in certain aspects. In this regard, FIG. 4 shows an example of an integrated system 410 including power switches 420-1 to 420-n, a power distribution network 415, a circuit 430, and a power switch controller 440. The power distribution network 415 provides a supply voltage V_{DD} (e.g., from a power management integrated circuit (PMIC)). The power switches 420-1 to 420-n are coupled between the power distribution network 415 and the circuit 430 to control power to the circuit 430. The circuit 430 may include at least one of a processor, a memory, sequential logic, a modem, and/or another type of circuit.

The power switch controller 440 is coupled to the power switches 420-1 and 420-n, and is configured to control the on/off states of the power switches 420-1 to 420-n. For example, the power switch controller 440 may turn off the power switches 420-1 to 420-n when the circuit 430 is not active (e.g., in an inactive mode) to conserve power, and turn on the power switches 420-1 to 420-n when the circuit 430 is active (e.g., in an active mode). When the circuit 430 is powered up from an inactive state to an active state, the power switch controller 440 may also time the turn on of each power switch 420-1 to 420-n based on a power-up timing sequence.

As shown in FIG. 4, the power switches 420-1 to 420-n may be implemented with respective transistors 280-1 to 280-n where each of the transistors 280-1 to 280-n may be a separate instance of the transistor 280 or may be an array of transistors including multiple instances of the transistor 280. Each of the power switches 420-1 to 420-n may be integrated on the die 205. In this example, each of the power switches 420-1 to 420-n has a respective gate terminal 422-1 to 422-n coupled to the gate metal layers 270 and 272 of the respective transistor 280-1 to 280-2. The gate terminal 422-1 to 422-n of each of the power switches 420-1 to 420-n is coupled to the power switch controller 440. In this example, the power switch controller 440 controls the on/off state of each of the power switches 420-1 to 420-n by controlling the voltage applied to the respective gate terminal 422-1 to 422-n.

Each of the power switches 420-1 to 420-n also has a respective first source/drain terminal 424-1 to 424-n coupled to the circuit 430, and a respective second source/drain terminal 426-1 to 426-n coupled to the power distribution network 415. The first source/drain terminal 424-1 to 424-n of each of the power switches 420-1 to 420-n may be coupled to a first subset of the source/drain metal layers 275 of the respective transistor 280, and the second source/drain terminal 426-1 to 426-n of each of the power switches 420-1 to 420-n may be coupled to a second subset of the source/drain metal layers 275 in the respective transistor 280. The source/drain metal layers 275 in the first subset may be interleaved with the source/drain metal layers 275 in the second subset. For example, the source/drain metal layers 275 in the first subset may be coupled to the source/drain contact layers 235-1, 235-3, 235-5, and 235-7, and the source/drain metal layers 275 in the second subset may be coupled to the source/drain contact layers 235-2, 235-4, 235-6, and 235-8, or vice versa.

It is to be appreciated that the transistor 280 is not limited to a power switch and may be used in other types of switches or devices. For example, the transistor 280 may be used in other applications where switches with low on-resistance are desirable.

Implementation examples are described in the following numbered clauses:

1. A die, comprising:
fins extending in a first direction;
gates formed over the fins, wherein the gates extend in a second direction that is perpendicular to the first direction;
source/drain contact layers formed over the fins, wherein the source/drain contact layers extend in the second direction, and the gates and the source/drain contact layers are interleaved;
a first gate metal layer;
a second gate metal layer, wherein the source/drain contact layers are between the first gate metal layer and the second gate metal layer in the second direction;
first gate vias electrically coupling the first gate metal layer to the gates; and
second gate vias electrically coupling the second gate metal layer to the gates.

2. The die of clause 1, further comprising:
source/drain vias disposed on the source/drain contact layers; and
source/drain metal layers, wherein each of the source/drain metal layers extends over at least a portion of a respective one of the source/drain contact layers, and each of the source/drain metal layers is electrically coupled to the respective one of the source/drain contact layers by a respective subset of the source/drain vias.

3. The die of clause 2, wherein:
a first portion of each of the source/drain contact layers extends pass a first end of the respective one of the source/drain metal layers in the second direction; and
the first portion of each of the source/drain contact layers extends over a first one or more of the fins.

4. The die of clause 3, wherein:
a second portion of each of the source/drain contact layers extends pass a second end of the respective one of the source/drain metal layers in the second direction; and
the second portion of each of the source/drain contact layers extends over a second one or more of the fins.

5. The die of clause 4, wherein the first end and the second end of each of the source/drain metal layers are opposite ends.

6. A die, comprising:
first fins extending in a first direction;
second fins extending in the first direction;
gates formed over the first fins and the second fins, wherein the gates extend in a second direction that is perpendicular to the first direction, and each of the gates extends contiguously over the first fins and the second fins;
first source/drain contact layers formed over the first fins, wherein the first source/drain contact layers extend in the second direction, and the gates and the first source/drain contact layers are interleaved;
second source/drain contact layers formed over the second fins, wherein the second source/drain contact layers extend in the second direction, and the gates and the second source/drain contact layers are interleaved;
a first gate metal layer;
a second gate metal layer, wherein the first source/drain contact layers are between the first gate metal layer and the second gate metal layer in the second direction;
a third gate metal layer, wherein the second source/drain contact layers are between the second gate metal layer and the third gate metal layer in the second direction;
first gate vias electrically coupling the first gate metal layer to the gates;
second gate vias electrically coupling the second gate metal layer to the gates; and
third gate vias electrically coupling the third gate metal layer to the gates.

7. The die of clause 6, further comprising:
first source/drain vias disposed on the first source/drain contact layers; and
first source/drain metal layers, wherein each of the first source/drain metal layers extends over at least a portion of a respective one of the first source/drain contact layers, and each of the first source/drain metal layers is electrically coupled to the respective one of the first source/drain contact layers by a respective subset of the first source/drain vias.

8. The die of clause 7, wherein:
a first portion of each of the first source/drain contact layers extends pass a first end of the respective one of the first source/drain metal layers in the second direction; and
the first portion of each of the first source/drain contact layers extends over a first one or more of the first fins.

9. The die of clause 8, wherein:
a second portion of each of the first source/drain contact layers extends pass a second end of the respective one of the first source/drain metal layers in the second direction; and
the second portion of each of the first source/drain contact layers extends over a second one or more of the first fins.

10. The die of clause 9, wherein the first end and the second end of each of the first source/drain metal layers are opposite ends.

11. The die of any one of clauses 7 to 10, further comprising:
second source/drain vias disposed on the second source/drain contact layers; and
second source/drain metal layers, wherein each of the second source/drain metal layers extends over at least a portion of a respective one of the second source/drain contact layers, and each of the second source/drain metal layers is electrically coupled to the respective one of the second source/drain contact layers by a respective subset of the second source/drain vias.

12. A system, comprising:
a switch comprising:
fins extending in a first direction;
gates formed over the fins, wherein the gates extend in a second direction that is perpendicular to the first direction;
source/drain contact layers formed over the fins, wherein the source/drain contact layers extend in the second direction, and the gates and the source/drain contact layers are interleaved;
source/drain metal layers, wherein each of the source/drain metal layers extends over at least a portion of a respective one of the source/drain contact layers;
source/drain vias electrically coupling the source/drain contact layers to the source/drain metal layers;
a first gate metal layer;
a second gate metal layer, wherein the source/drain contact layers are between the first gate metal layer and the second gate metal layer in the second direction;
first gate vias electrically coupling the first gate metal layer to the gates; and
second gate vias electrically coupling the second gate metal layer to the gates;
a power switch controller coupled to the first gate metal layer and the second gate metal layer;
a power distribution network coupled to a first subset of the source/drain metal layers; and
a circuit coupled to a second subset of the source/drain metal layers.

13. The system of clause 12, wherein the power switch controller is configured to turn on the switch when the circuit is in an active mode, and turn off the switch when the circuit is in an inactive mode.

14. The system of clause 12 or 13, wherein the circuit includes at least one of sequential logic, a processor, modem, and a memory.

15. The system of any one of clauses 12 to 14, wherein the switch is integrated on a die.

16. The system of clause 15, wherein:
a first portion of each of the source/drain contact layers extends pass a first end of the respective one of the source/drain metal layers in the second direction; and
the first portion of each of the source/drain contact layers extends over a first one or more of the fins.

17. The system of clause 16, wherein:
a second portion of each of the source/drain contact layers extends pass a second end of the respective one of the source/drain metal layers in the second direction; and
the second portion of each of the source/drain contact layers extends over a second one or more of the fins.

18. The system of clause 17, wherein the first end and the second end of each of the source/drain metal layers are opposite ends.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “approximately”, as used herein with respect to a stated value or a property, is intended to indicate being within 10% of the stated value or property. The term “coupled” or “coupling” is used herein to refer to the direct or indirect electrical coupling between two structures.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A die, comprising:
fins extending in a first direction;
gates formed over the fins, wherein the gates extend in a second direction that is perpendicular to the first direction;
source/drain contact layers formed over the fins, wherein the source/drain contact layers extend in the second direction, and the gates and the source/drain contact layers are interleaved;
a first gate metal layer;
a second gate metal layer, wherein the source/drain contact layers are between the first gate metal layer and the second gate metal layer in the second direction;
first gate vias electrically coupling the first gate metal layer to the gates; and
second gate vias electrically coupling the second gate metal layer to the gates.

2. The die of claim 1, further comprising:
source/drain vias disposed on the source/drain contact layers; and
source/drain metal layers, wherein each of the source/drain metal layers extends over at least a portion of a respective one of the source/drain contact layers, and each of the source/drain metal layers is electrically coupled to the respective one of the source/drain contact layers by a respective subset of the source/drain vias.

3. The die of claim 2, wherein:
a first portion of each of the source/drain contact layers extends pass a first end of the respective one of the source/drain metal layers in the second direction; and
the first portion of each of the source/drain contact layers extends over a first one or more of the fins.

4. The die of claim 3, wherein:
a second portion of each of the source/drain contact layers extends pass a second end of the respective one of the source/drain metal layers in the second direction; and
the second portion of each of the source/drain contact layers extends over a second one or more of the fins.

5. The die of claim 4, wherein the first end and the second end of each of the source/drain metal layers are opposite ends.

6. A die, comprising:
first fins extending in a first direction;
second fins extending in the first direction;
gates formed over the first fins and the second fins, wherein the gates extend in a second direction that is perpendicular to the first direction, and each of the gates extends contiguously over the first fins and the second fins;
first source/drain contact layers formed over the first fins, wherein the first source/drain contact layers extend in the second direction, and the gates and the first source/drain contact layers are interleaved;
second source/drain contact layers formed over the second fins, wherein the second source/drain contact layers extend in the second direction, and the gates and the second source/drain contact layers are interleaved;
a first gate metal layer;
a second gate metal layer, wherein the first source/drain contact layers are between the first gate metal layer and the second gate metal layer in the second direction;
a third gate metal layer, wherein the second source/drain contact layers are between the second gate metal layer and the third gate metal layer in the second direction;
first gate vias electrically coupling the first gate metal layer to the gates;
second gate vias electrically coupling the second gate metal layer to the gates; and
third gate vias electrically coupling the third gate metal layer to the gates.

7. The die of claim 6, further comprising:
first source/drain vias disposed on the first source/drain contact layers; and
first source/drain metal layers, wherein each of the first source/drain metal layers extends over at least a portion of a respective one of the first source/drain contact layers, and each of the first source/drain metal layers is electrically coupled to the respective one of the first source/drain contact layers by a respective subset of the first source/drain vias.

8. The die of claim 7, wherein:
a first portion of each of the first source/drain contact layers extends pass a first end of the respective one of the first source/drain metal layers in the second direction; and
the first portion of each of the first source/drain contact layers extends over a first one or more of the first fins.

9. The die of claim 8, wherein:
a second portion of each of the first source/drain contact layers extends pass a second end of the respective one of the first source/drain metal layers in the second direction; and
the second portion of each of the first source/drain contact layers extends over a second one or more of the first fins.

10. The die of claim 9, wherein the first end and the second end of each of the first source/drain metal layers are opposite ends.

11. The die of claim 7, further comprising:
second source/drain vias disposed on the second source/drain contact layers; and
second source/drain metal layers, wherein each of the second source/drain metal layers extends over at least a portion of a respective one of the second source/drain contact layers, and each of the second source/drain metal layers is electrically coupled to the respective one of the second source/drain contact layers by a respective subset of the second source/drain vias.

12. A system, comprising:
a switch comprising:
fins extending in a first direction;
gates formed over the fins, wherein the gates extend in a second direction that is perpendicular to the first direction;
source/drain contact layers formed over the fins, wherein the source/drain contact layers extend in the second direction, and the gates and the source/drain contact layers are interleaved;
source/drain metal layers, wherein each of the source/drain metal layers extends over at least a portion of a respective one of the source/drain contact layers;
source/drain vias electrically coupling the source/drain contact layers to the source/drain metal layers;
a first gate metal layer;
a second gate metal layer, wherein the source/drain contact layers are between the first gate metal layer and the second gate metal layer in the second direction;
first gate vias electrically coupling the first gate metal layer to the gates; and
second gate vias electrically coupling the second gate metal layer to the gates;
a power switch controller coupled to the first gate metal layer and the second gate metal layer;
a power distribution network coupled to a first subset of the source/drain metal layers; and
a circuit coupled to a second subset of the source/drain metal layers.

13. The system of claim 12, wherein the power switch controller is configured to turn on the switch when the circuit is in an active mode, and turn off the switch when the circuit is in an inactive mode.

14. The system of claim 12, wherein the circuit includes at least one of sequential logic, a processor, modem, and a memory.

15. The system of claim 12, wherein the switch is integrated on a die.

16. The system of claim 15, wherein:
a first portion of each of the source/drain contact layers extends pass a first end of the respective one of the source/drain metal layers in the second direction; and
the first portion of each of the source/drain contact layers extends over a first one or more of the fins.

17. The system of claim 16, wherein:
a second portion of each of the source/drain contact layers extends pass a second end of the respective one of the source/drain metal layers in the second direction; and
the second portion of each of the source/drain contact layers extends over a second one or more of the fins.

18. The system of claim 17, wherein the first end and the second end of each of the source/drain metal layers are opposite ends.
